(19) United States
(12) Patent Application Publication
(10) Pub. No.: US 2003/0107363 A1
(43) Pub. Date: Jun. 12, 2003

(54) Low loss links between wafer probes and load pull tuner

(76) Inventor: Christos Tsironis, Montreal (CA)

Correspondence Address: CHRISTOS TSIRONIS, FOCUS MICROWAVES, 1603 REGIS ST., D.D.O., QC, H98-3H7, CA

(21) Appl. No.: 10/316,065

(22) Filed: Dec. 11, 2002

Related U.S. Application Data
(60) Provisional application No. 60/339,298, filed on Dec. 12, 2001.

(51) Int. Cl. G01R 23/04; G01R 25/02; G01R 27/02

(52) U.S. Cl. 324/95

(57) ABSTRACT

A method for establishing a low loss microwave link between load-pull tuners and microwave wafer probes is presented. This link consists of an extension of the coaxial airline of the tuner, an extension of the tuner slab line or a co-planar waveguide tuner extension that connects directly to wafer probes, a separate airline section or a separate prematching module.

### PRIORITY CLAIM

This application claims benefit of priority of U.S. Provisional Application Serial No. 60/339.298 filed on Dec. 12, 2001 entitled Low Loss Links between Wafer Probes and Lead Pull Tuners, whose inventor was Christos TSIRONIS.

### CROSS-REFERENCE TO RELATED APPLICATIONS

Not Applicable

### STATEMENT REGARDING FEDERALLY SPONSORED RESEARCH OR DEVELOPMENT

Not Applicable

### REFERENCE TO A SEQUENCE LISTING, A TABLE, OR A COMPUTER PROGRAM LISTING COMPACT DISC APPENDIX

Not Applicable

### BACKGROUND OF THE INVENTION

1. Field of the Invention

This invention relates to the establishment of low loss microwave transmission links between automatic or manual load or source pull microwave tuners on one hand and microwave wafer probes on the other hand used on a manual or automatic wafer probe station

2. Description of the Prior Art

A major problem in wafer probing very low or very high impedance microwave transistors and circuits is created by the insertion loss of the microwave transmission link between the wafer probes used to access the chip or device under test (DUT) and the tuners used in testing, such as, power load pull, or low noise characteristics testing.

It is very important to be able to tune to very high reflection factors (corresponding to very low or very high Radio Frequency (RF) or microwave impedances) at the device reference plane. The insertion loss of the microwave link between tuner and wafer probe reduces this reflection factor and therefore the tuning range of the tuners. By consequence, this limits the test capability of the test set-up.

Existing set-ups use commercially available microwave flexible or semi-rigid coaxial cables to generate this link (FIG. 1). This type of cable is lossy, especially at microwave and millimeter-wave frequencies (above 5 GHz and up to 110 GHz).

These losses stem essentially from the fact that such flexible or semi-rigid cables use various dielectric materials, such as Teflon, as a core material between their central conductor and external cylindrical ground. These cables also require two lossy connectors used to connect the tuner to the said RF cable and then the cable to the wafer probe.

FIG. 1 depicts the Prior Art, illustrating how the connection uses flexible or semi rigid cable.

As shown in FIG. 1 an automatic or manual tuner (6) has a coaxial test port (12). The other coaxial output (7) of the tuner (6) is connected to the test set-up outside of the FIG. 1, which is configured in a traditional manner and is of no significance for this patent. The test port (12) of the tuner (6) is connected via a flexible or semi-rigid cable (4) with the commercially available wafer probe (1). This cable includes a body (4) and two coaxial connectors (3 & 5). Connector (5) is attached to the tuner test port (12) and the connector (3) to the wafer probe (1). Probe (1) is fixed to the probe station (8) using commercially available probe positioners. Probe (1) is being positioned in a way as to touch with its RF extremity (11) the device under test (DUT ) (10), which is part of a semiconductor wafer (2), in order to allow RF energy flow through the DUT. The semiconductor wafer (2) is placed on a chuck (9), which, in general, can be moved by means of micrometric screws (13 & 14) in such a way as to establish precise and reliable contact of the probe (1) with the DUT chip (10).

This traditional set-up allows testing of the DUT for linearity, S-parameter measurements and limited Load Pull and Noise parameter.

However, it is a shortcoming of this technology that the cable (4) with the two connectors (3 & 5) has insertion loss at RF and microwave frequencies, which reduces the reflection factor generated by the tuner (6) at its port (12). This is an important limitation of the test capacity, because modern semiconductor chips (10) often have very high or very low internal impedance, corresponding in both cases to very high reflection factors, which cannot be reached by the tuning capability of available manual or automatic tuners, if they are using such an RF cable (4) to establish a link with the wafer probe. At this point in time, there are no practical solutions to this problem, which limits the testability of very low noise and very high power semiconductor chips.

### BRIEF SUMMARY OF THE INVENTION

This invention describes new methods for establishing low loss microwave transmission links between automatic or manual load or source pull microwave tuners on one hand and microwave wafer probes used on a manual or automatic wafer probe station on the other hand.

In order to solve the problems referred to in ‘BACKGROUND TO THE INVENTION’ and to reduce the insertion loss of the microwave link between the tuner and the wafer probe we propose the following solution:

Instead of using a microwave flexible or semi-rigid cable we propose one of these solutions:

1. To extend the airline of the tuner until it reaches the wafer probe thus eliminating both, the dielectric loss of the cable and one of the two lossy connectors of this cable, depending on the configuration; or;

2. Use a separate module made of coaxial or parallel-plate (slabline) airline, which does not use any dielectric, thus producing less insertion loss. In this second case we do not save the second connector, but we avoid the loss due to the dielectric material in the RF cable. The said separate module comprising a straight or bent section of airline and two connectors on each end; or a straight or bent section of parallel-plate airline (slabline), two connectors at its ends and means of adjustable tuning using metallic or dielectric probes insertable into the slabline, in order to generate a prematching reflection; or;

3. Coplanar waveguide (CPWG) airline extension used to form a wafer probe at one end.

The extension of the tuner airline, until it reaches the wafer probes, can be:—

a. In form of a coaxial airline, or

b. In form of a slabline (or parallel-plate airline) or

c. In form of a coplanar waveguide airline.

In the case of the coplanar waveguide airline extension (item c) it is proposed to machine and shape the end of the airline itself into the form of coplanar wafer probes, similar to already available wafer probes, which will connect directly on the device under test (DUT). The structure of the wafer probes themselves, are readily commercially available and are themselves not part of this invention.

Whereas solutions a. and b. above eliminate the insertion loss of the cable used hitherto and one connector, the last configuration c. offers the additional advantage of eliminating also the last remaining coaxial connector/adapter between the airline and the wafer probe, thus further reducing the loss of the tuner-device transition to an absolute minimum and this way increasing the tuning range of the tuners at DUT reference plane to an absolute maximum.

Important implementary actions of the invention are as follows:

1. Straight Coaxial Airline extension between the tuner and the wafer probe

2. Straight slabline extension between the tuner and the wafer probe

3. Bent (30° or 45°) slabline extension between the tuner and the wafer probe.

4. Straight or bent slabline extension as a separate module linked with the tuner via a microwave connector.

5. Prematching module included on items 1. to 3., in order to increase reflection factor very close to the device under test.

6. Coplanar waveguide (CPWG) extension of the tuner airline (slabline) to form at the end a wafer probe itself.

7. Method for replacing the components of the CPWG attached to the tuner for maintenance purposes.

8. Method of aligning the characteristic impedance and the geometrical configuration of the CPWG airline extension at the level of the probe tips.

### BRIEF DESCRIPTION OF THE SEVERAL VIEWS OF THE DRAWING

The invention and its mode of operation will be more clearly understood from the following detailed description when read with the appended drawing in which:—

FIG. 1 depicts a perspective view of the Prior Art; connection uses flexible or semi-rigid cable

FIG. 2 depicts a perspective view of a Coaxial straight airline extension

FIG. 3 depicts a perspective view of a straight slabline extension

FIG. 4 depicts a perspective view of a bent slabline extension

FIG. 5 depicts a perspective view of a Coplanar waveguide airline extension

FIG. 6 depicts a perspective view of a Coplanar Probe

FIG. 7 depicts a perspective view of a pre-matching module

### DETAILED DESCRIPTION OF THE INVENTION

This invention is described in the following description with reference to the FIGS., in which like numbers represent the same or similar elements.

We propose solutions to the problem of reduction of tuning range of the Load Pull tuner due to the losses of the semi-rigid cable as defined in the prior art by replacing the said cable by an extension (17) of the airline, which is the transmission line (16) inside the tuner (15).

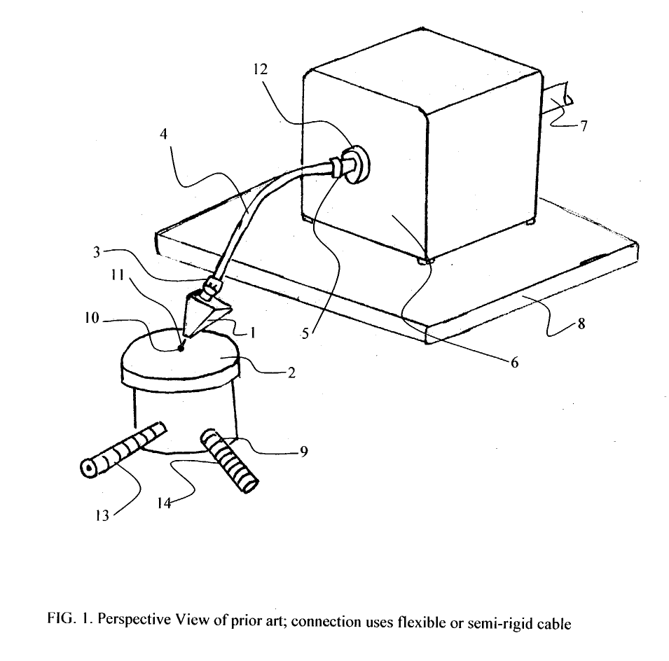

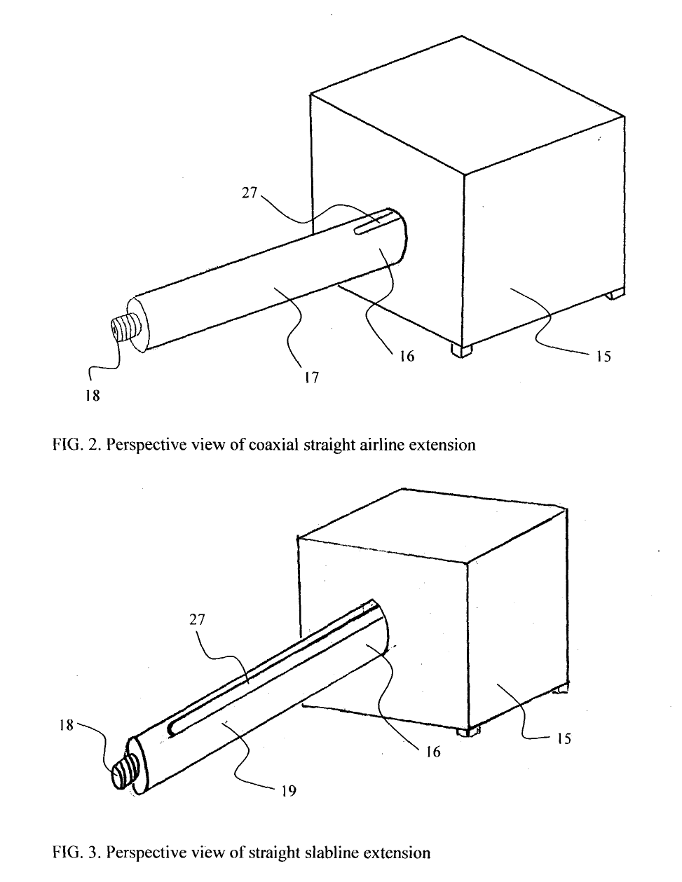

The end of the transmission line (17), which is a coaxial male or female connector (18), can be directly attached to the wafer probe (1) (FIG. 1). FIG. 2 shows a coaxial extension of the slabline (16) inside the tuner (15). Because there is no connector and adapter at the point where the slabline (16) joins the airline (17), this reduces microwave losses of the transition. Because the airline extension (17) does not require any dielectric support material to separate its central conductor from the external ground conductor, this configuration further reduces the loss of the connection between the tuner (15) and the connector (18), which will be attached to the probe (1).

Furthermore we propose an alternative solution to FIG. 2, which consists of using an extension of the slabline (16) of the tuner. This solution (FIG. 3) has the advantage of easier manufacturability, because the slabline extension (19) has no junction and change of propagation modes from slabline to coaxial as has the solution of FIG. 2 at the point where the slabline (16) joins the extension (17).

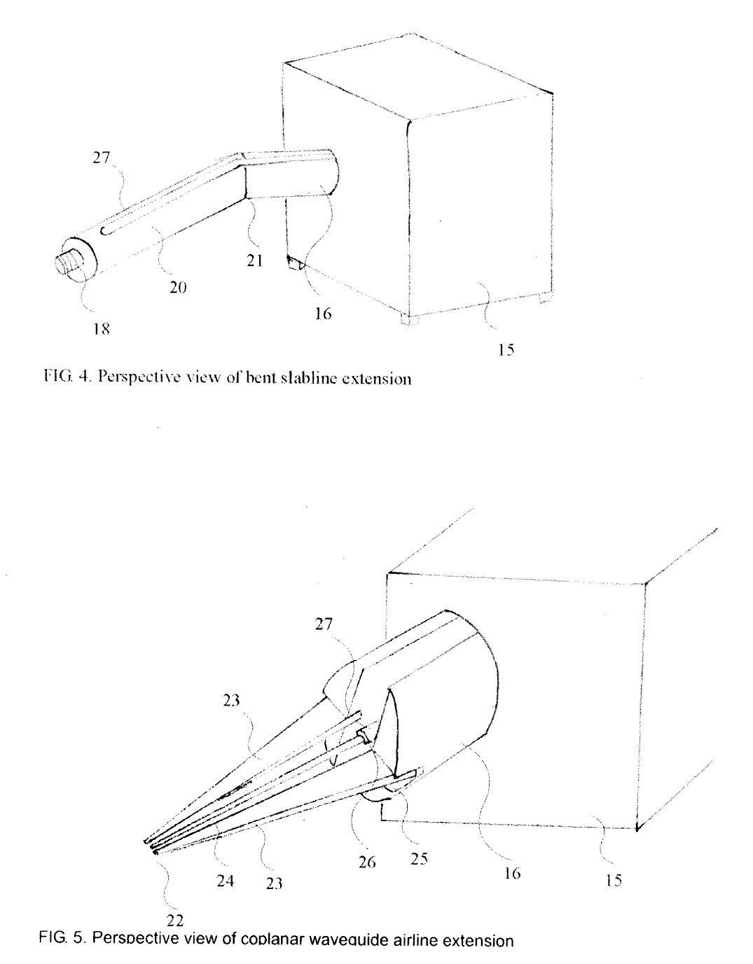

Furthermore, in order to accommodate for the configuration of commercial wafer probes (1), which have a connector angled at 30° or 45° or 90°, compared to the plane of the wafer (2) we propose to configure the slabline extension (20) at an angle (21) of 30°, 45° or 90° outside the tuner (15) (FIG. 4). This solution (FIG. 4) has the additional advantage of accommodating for the angled (21) probes (1) thus allowing the tuner (15) to be positioned horizontally on the wafer probe station (8).

In order to further improve the losses of the connection between the tuner (15) and probe (1), we propose a configuration, which eliminates also connector (18) in FIGS. 2, 3 and 4. This is achieved by replacing the slabline structure (20) in FIG. 4 by another means of transmission line, known as coplanar waveguide (CPWG).

This structure allows a continuous transition between the slabline structure (16) in the tuner (15) and the probe tips (22), which are of coplanar structure themselves.

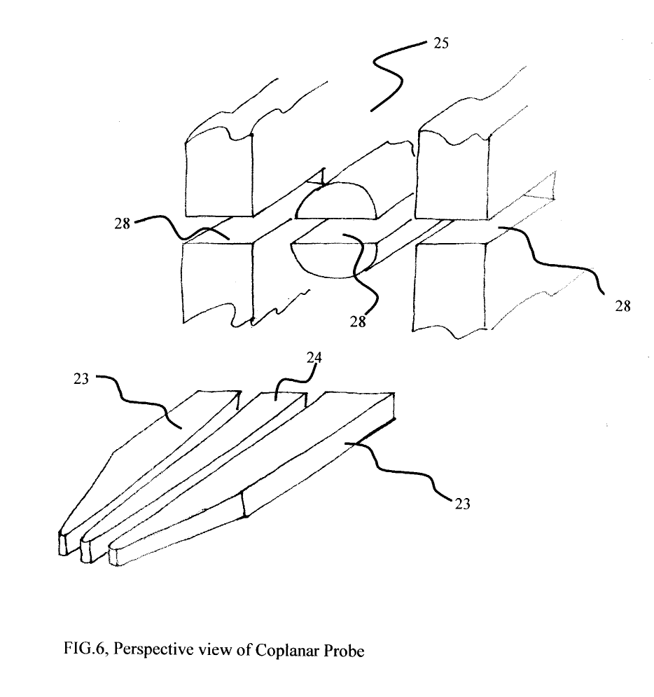

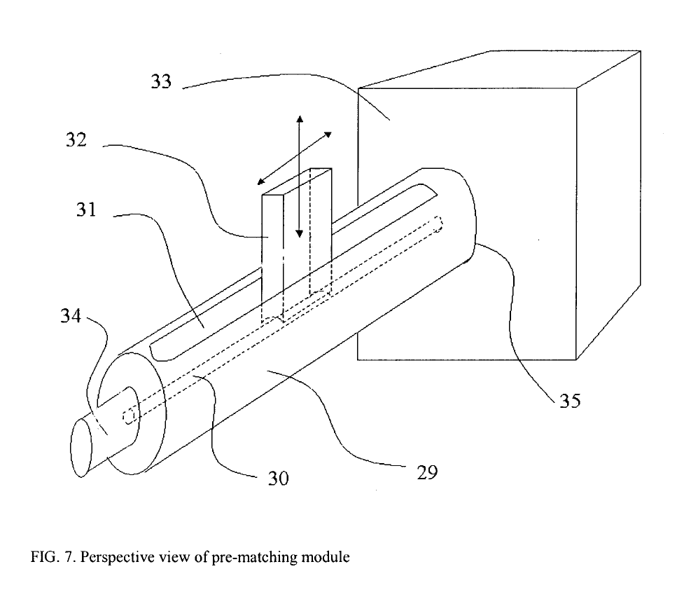

The arrangement in FIG. 6 is such that the angle at which the side plates (23) of the coplanar waveguide structure (23 & 24) enter the slots in the slabline (25) can be adjusted; as such then also the distance between the central conductor of the CPWG structure (24) and the side walls (23) can be adjusted to provide any characteristic impedance as required by the test devices (10) (typically 50 ohm). Maintenance is provided by removal of the CPWG sides from the slots (28) in the slabline.

Furthermore, in order to reduce the loss of the CPWG structure (23 & 24), we propose a modified CPWG arrangement, in which the side plates (23) of the structure do have certain thickness towards the insertion slot (25) in the slabline walls (16), this thickness being approximately 2.5 times the diameter of the central conductor (24) of the CPWG structure (23 & 24) and maintain this ratio of 2.5 towards the tips (22) of the structure as the diameter of the central conductor (24) gradually decreases to meet the required size for the test device (10). Only at the very end of the modified CPWG structure the sidewalls (23) will have to be very thin in order to maintain the mechanical elasticity required for good electrical galvanic contact between the probe tips (22) and the device under test (10).

Furthermore, in order to increase the reflection factor available at DUT reference plane, the low loss link made by the extension of the slotted slabline (29) of the tuner (33) can be fitted by means of pre-matching tuning in form of a metallic or dielectric probe (32), which said probe can be moved in and out of the slot of the slabline (29) in order to modify the amplitude of the reflection factor presented to the DUT at port (34) and said probe can be moved along the slotted slabline (29) in order to modify the phase of the reflection factor presented to the DUT at port (34). Said slabline extension (29) can be either part of the tuner slabline or a separate unit joined at plane (35) with the tuner slabline by means of a coaxial connector (not shown). Furthermore this pre-matching tuning technique can be applied to all hitherto described low loss links either straight or bent and can be integrated either on the horizontal portion of the slabline (19) or on the sloped portion (20).

Although the present invention has been explained hereinabove by way of a preferred embodiment thereof, it should be pointed out that any modifications to this preferred embodiment within the scope of the appended claims is not deemed to alter or change the nature and scope of the present invention.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What I claim as my invention is:

1. Means for establishing low loss microwave links between the test port of microwave load pull tuners and microwave wafer probes by extending the tuner's transmission airline up to the probe connector, said extension being either part of the said tuner airline itself or a separate unit inserted between the tuner test port and the coaxial or waveguide connector of the wafer probe, said microwave tuners being used either for power load pull testing or for noise measurement testing.

2. Said low loss links, as in claim 1, made as a straight coaxial airline extension of the microwave tuner at its test port.

3. Said low loss links, as in claim 1, made as a straight parallel-plate airline (slabline) extension of the microwave tuner at its test port.

4. Said low loss links, as in claim 1, made as a coaxial airline extension bent by 30°, 45° or 90° approximately, in order to compensate for the angle difference between the axis of the connector of the wafer probes and the horizontal airline of the tuner.

5. Said low loss links, as in claim 1, made as a parallel-plate airline (slabline) bent by 30°, 45° or 90° approximately, in order to compensate for the angle difference between the axis of the connector of the wafer probes and the horizontal airline of the tuner.

6. Straight parallel-plate (slabline) or coaxial airline extension, comprising an airline and two microwave connectors, configured as a separate module, inserted between the wafer probe and the tuner test port, as in claim 1.

7. Parallel-plate (slabline) or coaxial airline extension, bent by 30°, 45° or 90° approximately, comprising an airline and two microwave connectors, configured as a separate module, inserted between the wafer probe and the tuner test port, as in claim 1, and used to compensate for the angle difference between the axis of the wafer probe and the airline of the tuner.

8. Prematching module in form of a parallel-plate (slabline) or slotted coaxial airline in form of a straight structure, as in claim 6, comprising an airline and two microwave connectors, and means to generate microwave reflection by inserting a metallic or dielectric probe inside the slotted or parallel-plate airline, said prematching module operating very close to the DUT (device under test) and used in order to increase the reflection factor presented to the DUT by the microwave tuner.

9. Prematching module in form of a parallel-plate (slabline) or slotted coaxial airline in form of a structure bent by 30°, 45° or 90° approximately, as in claim 7, comprising an airline and two microwave connectors, and means to generate microwave reflection by inserting a metallic or dielectric probe inside the slotted or parallel-plate airline, said prematching module operating very close to the DUT (device under test) and used in order to increase the reflection factor presented to the DUT by the microwave tuner.

10. Extension of the tuner airline (slabline) at the tuner test port, as in claim 1, said extension to be made in form of a coplanar waveguide (CPWG), said CPWG extension to be formed at the end close to the DUT as a wafer probe itself.

11. A method for replacing the components of the CPWG extension attached to the tuner for maintenance and repair purposes.

12. A method of aligning the characteristic impedance of the CPWG airline extension by changing the geometrical configuration at the level of the probe tips.
